(19) United States
(12) Patent Application Publication
(10) Pub. No.: US 2004/0183180 A1
(43) Pub. Date: Sep. 23, 2004

(54) Multi-chips stacked package

(75) Inventors: Chih-Ming Chung, Kaohsiung (TW); Sung-Fei Wang, Kaohsiung (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaohsiung (TW)

(21) Appl. No.: 10/747,036

(22) Filed: Dec. 30, 2003

(30) Foreign Application Priority Data
Mar. 21, 2003 (TW) 092106422

(51) Int. Cl. H01L 23/02

(52) U.S. Cl. 257/686

(57) ABSTRACT

A multi-chips stacked package mainly comprises a substrate, a lower chip, an upper chip and a supporter. The substrate has an upper surface, and the upper chip is disposed on the upper surface of the substrate and electrically connected to the substrate. The supporter has a carrying portion and at least a supporting portion connecting to the carrying portion and disposing on the substrate. In such a manner, the carrying portion covers the lower chip. Besides, the upper chip is disposed on the carrying portion of the supporter and electrically connected to the substrate.

### BACKGROUND OF THE INVENTION

1. Field of Invention

This invention relates to a multi-chips stacked package. More particularly, the present invention is related to a multi-chips stacked package having a supporter to carry semiconductor chips.

2. Related Art

Recently, integrated circuit (chip) packaging technology is becoming a limiting factor for the development in packaged integrated circuits of higher performance. Semiconductor package designers are struggling to keep pace with the increase in pin count, size limitations, low profile, and other evolving requirements for packaging and mounting integrated circuits.

Due to the assembly package in miniature and the integrated circuits operation in high frequency, MCM (multi-chips module) package is commonly used in said assembly package and electronic devices. Usually, said MCM package mainly comprises at least two semiconductor chips encapsulated therein, for example a processor unit, a memory unit and related logic units, so as to upgrade the electrical performance of said assembly package. In addition, the electrical paths between the chips in said MCM package are short so as to reduce the signal delay and save the reading and writing time.

Generally speaking, a conventional MCM package shall be a multi-chips side-by-side package or a multi-chips stacked package. As shown in FIG. 1, it illustrates a multi-chips stacked package and said stacked package is formed by disposing an upper chip 12 on a lower chip 14 by wire-bonding and chip-stacking technology, electrically connecting the upper chip 12 and the lower chip 14 to a substrate 16 respectively. However, when the number of I/O pins is increased, the electrically conductive wires 17 and 18 are more adjacent to each other. Accordingly, when the upper chip 12, the lower chip 14, the substrate 16, and the electrically conductive wires 17 and 18 are encapsulated in an encapsulation 19, the electrically conductive wires 17 and 18 are directly contacted with each other and short-circuited by encapsulation sweeping the electrically conductive wires. In order to solve this problem, said design illustrating in FIG. 2 are provided. As shown in FIG. 2, there is provided an upper chip 22, a dummy chip 23 and a lower chip 24 smaller than the upper chip 22 in size wherein the dummy chip 23 is disposed between the upper chip 22 and the lower chip 24 so that the dummy chip 23 will provide a space for providing the lower chip 22 a wire-bonding space. In such a manner, the upper chip 22 and the lower chip 24 can be electrically connected to the substrate 26 respectively by electrically conductive wires 27 and 28 without having the electrically conductive wires 27 and 28 interfered with each other when the encapsulation encloses said upper chip 22, the dummy chip 23 and the lower chip 24 to complete the packaging process.

However, as mentioned above, there are several disadvantages as following shown. When the thickness of the upper chip 22 is less than 5.5 mils, the upper chip 22 will be damaged and cracked during the wire-bonding operation. It should be noted when the upper chip 22 overhangs the dummy chip 23 with a distance larger than 2.5 mm, namely, the distance between the edge of the upper chip 22 and the edge of the dummy chip 23 is larger than 2.5 mm, it is easy to cause the upper chip 22 to be cracked by the electrically conductive wires 27 bonding the upper chip 22 to the substrate 26. Particularly, the thickness of the upper chip 22 is smaller than 5.5 mils, it will more easily cause the upper chip 22 to be damaged by electrically conductive wires 27 bonding the upper chip 22 to the substrate 26. Consequently, the size of the upper chip 22 depends upon the size of the dummy chip 23. However, the dummy chip 23 is elected upon the size of the lower chip 24 to provide a space for the electrically conductive wire 27 bonding the lower chip 24 to the substrate 26, so that the size of the upper chip is limited and restricted by the above reason.

Therefore, providing another assembly package to solve the above-mentioned disadvantages is the most important task in this invention.

### SUMMARY OF THE INVENTION

In view of the above-mentioned problems, an objective of this invention is to provide a multi-chips stacked package with a supporter disposed between an upper chip and a lower chip, wherein the upper chip is disposed on the supporter and the supporter is disposed above the lower chip. Accordingly, the upper chip can be prevented from being cracked when the electrically conductive wire bonding the upper chip to the substrate.

To achieve the above-mentioned objective, a multi-chips stacked package is provided, wherein the multi-chips stacked package mainly comprises a substrate, an upper chip, a lower chip and a supporter. Therein, the substrate has an upper surface for disposing the lower chip and the lower chip is electrically connected to the substrate. Said supporter has a carrying portion and a supporting portion wherein the carrying portion connects to the supporting portion, and the supporting portion is attached on the substrate so that the carrying portion is able to cover the lower chip. Moreover, the upper chip is disposed on the carrying portion and electrically connected to the substrate. Preferably, the supporter may be a cap-like one.

As mentioned above, the supporter can be any kind of designs according to the size of the upper chip. Accordingly, the upper chip can be entirely disposed on the carrying portion of the supporter without any portions overhanging the supporter, or the upper chip can overhang the supporter with a distance less than 2.5 mm. In such a manner, no matter what the size of the upper chip is, the upper chip will not be cracked due to the smaller thickness when the electrically conductive wires bond the upper chip to the substrate by wire-bonding technology. Moreover, the supporter can also be a thermally conductive device, for example a heat spreader, so as to transmit the heat generated from the upper chip to external devices through the substrate. Besides, when the lower chip is a high-frequency chip, the supporter can be electrically grounded to the substrate to provide an electrical shield to avoid noise and cross-link in the operation of the electrical signals.

### BRIEF DESCRIPTION OF THE DRAWINGS

The invention will become more fully understood from the detailed description given herein below illustrations only, and thus are not limitative of the present invention, and wherein:

FIG. 1 is a cross-sectional view of the conventional multi-chips stacked package;

FIG. 2 is a cross-sectional view of another conventional multi-chips stacked package;

FIG. 3 is a cross-sectional view of a multi-chips stacked package according to the first embodiment;

FIG. 4 is a cross-sectional view of a multi-chips stacked package according to the second embodiment;

FIG. 5 is a cross-sectional view of a multi-chips stacked package according to the third embodiment;

FIG. 6 is a cross-sectional view of a multi-chips stacked package according to the fourth embodiment; and

FIG. 7 is a cross-sectional view of a multi-chips stacked package according to the fifth embodiment.

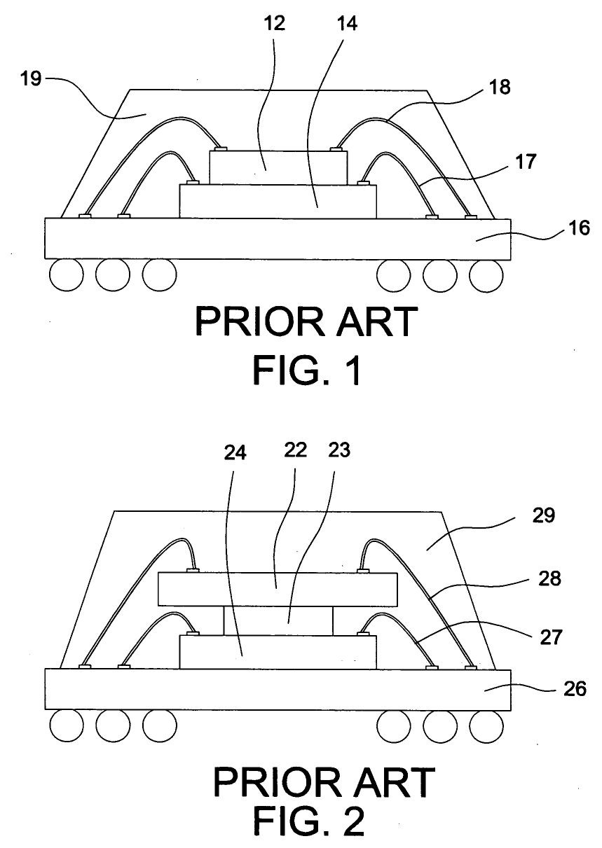

### DETAILED DESCRIPTION OF THE INVENTION

The multi-chips stacked package according to the preferred embodiment of this invention will be described herein below with reference to the accompanying drawings, wherein the same reference numbers refer to the same elements.

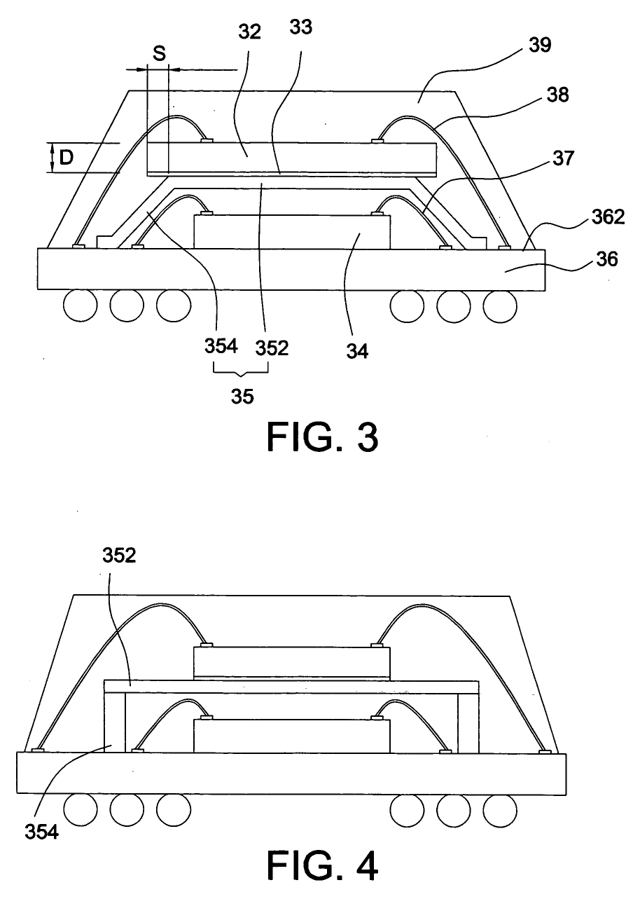

In accordance with a first preferred embodiment as shown in FIG. 3, there is provided a multi-chips stacked package. The multi-chips stacked package mainly comprises an upper chip 32, a lower chip 34, a supporter 35 and a substrate 36. Therein, the substrate 36 has an upper surface 362, and the lower chip 34 is disposed on the upper surface 362 of the substrate 36 and electrically connected to the substrate 36. In addition, the supporter 35 is cap-like and has a carrying portion 352, for example a flat plate, and a supporting portion 354 connecting to the carrying portion 352. Accordingly, when said supporting portion 354 is mounted on the upper surface 362 of the substrate 36 so as to have the carrying portion 352 covered the lower chip 34 and the electrically conductive wires 37. Moreover, the upper chip 32 is mounted on the carrying portion 352 of the supporter 35 via an adhesive layer 33 and electrically connected to the substrate 36 via the electrically conductive wires 38. Besides, said multi-chips stacked package further comprises an encapsulation 39 covering the upper chip 32, the lower chip 34, the supporter 35, the substrate 36, and the electrically conductive wire 37 and 38. Moreover, the supporting portion 354 may be a ring or is composed of slant columns connecting to the carrying portion.

It should be noted that the supporter 35 is connected to and disposed above the upper surface 362 of the substrate 36 by the supporting portion 354 so as to define a distance between the carrying portion 352 and the lower chip 34 to provide a space for the electrically conductive wires 37 bonding the lower chip 34 to the substrate 36. Generally speaking, when the thickness of the upper chip 32 “D” is smaller than 5.5 mils and said distance “S” is longer than 2.5 mm as shown in FIG. 3, the upper chip 32 will be easily damaged and cracked in the operation of the wire-bonding process. However, in this invention, the supporter 35 can be different sizes according to the size of the upper chip 32 so that the entire upper chip 32 is able to be disposed on the carrying portion 352, or the upper chip 32 overhangs the supporter 35 with a distance less than 2.5 mm. Accordingly, the distance “S” between the edge of the upper chip 32 and the edge of the carrying portion 35 as shown in FIG. 3 will be well controlled due to different supporter design, so the upper chip 32 can be prevented from damaging and cracking in the operation of the wire-bonding process due to the smaller thickness of the upper chip 32 “D” or the longer distance “S” between the edge of the upper chip 32 and the edge of the carrying portion 35 as shown in FIG. 3. Besides, the carrying portion 352 and the supporting portion 354 can be formed and manufactured integrally. In addition, the carrying potion 352 and the supporting portion 354 can be manufactured respectively and then connected to each other with an adhesive material to form another supporter in the shape of “ [symbol] ” as shown in FIG. 4. Namely, the supporter may a cap one.

As mentioned above, the supporter 35 can be also a heat spreader with a carrying portion 352 and a supporting portion 354. For example, the heat spreader is made of copper metal so as to be regarded as a thermally conductive device for transmitting the heat generated from the upper chip 32 to the substrate 36. In addition, a thermally conductive adhesive 33 is interposed between the upper chip 32 and the heat spreader 35 to upgrade the performance of heat dissipation. Besides, a protrusion 356 is formed at the bottom of the carrying potion 352 so as to connect the lower chip 34 and transmit the heat generated from the upper chip 32 and the lower chip 34 to external devices, for example motherboards, through the substrate 36.

As mentioned above, when the lower chip 34 is a high-frequency chip, the upper chip 32 will be affected more easily by the noise and the cross talk of the electrical signals. However, when the supporter 35 is electrically grounded to the substrate 36, the supporter 35 will provide a good electrical shielding to upgrade the electrical performance of the package.

In addition, the transmitting speed of the electrical signals is based upon the circumambient environment. For example, when the chip is enclosed by an encapsulation, the transmitting speed of the electrical signals will be slower than that when the chip is enclosed by air. In other words, there is a lot of signal decay when the chip is enclosed by an encapsulation, especially for high-frequency chip. Accordingly, as shown in FIG. 6, the space between the lower chip 34 and the supporter 35 or the upper surface 362 of the substrate 36 and the supporter 35 can be filled with air 31 only and the space outside the supporter 35 can be filled with an encapsulation 39 to enclose the upper chip 32 so as to solve above-mentioned questions.

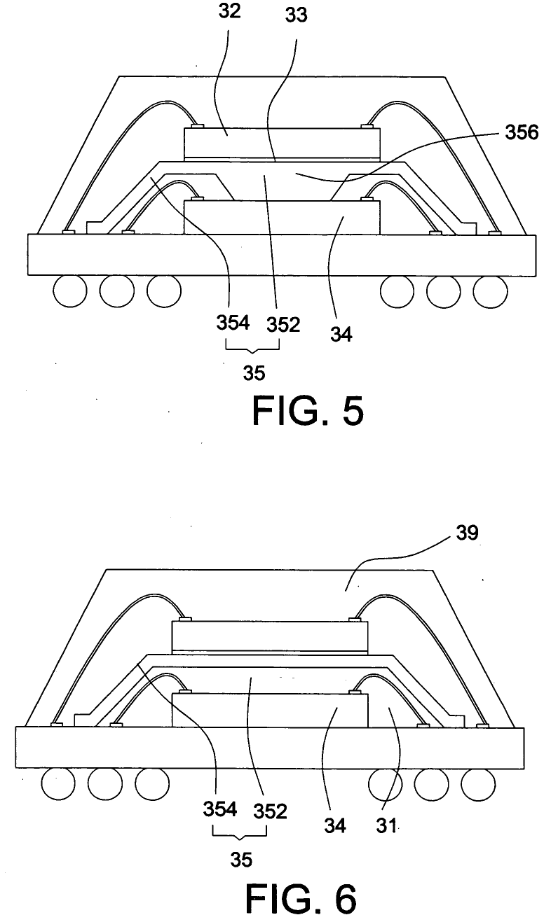

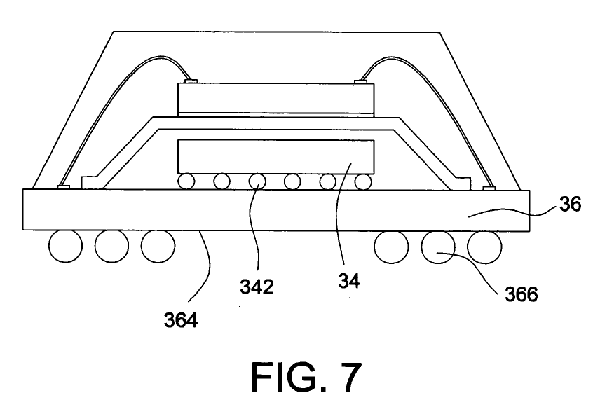

Next, referring to FIG. 7, the lower chip 34 can be electrically connected to and bonded to the substrate 36 via a plurality of electrically conductive bumps 342 so as to improve the electrical performance of the package. Moreover, from FIG. 3 to FIG. 7, there are a plurality of solder balls 366 formed on the lower surface 364 of the substrate 36 to be electrical paths for electrically connecting to external devices. It should be noted that the reference numeral of each element shown in FIGS. 4, 5, 6, and 7 are corresponding the reference one provided in FIG. 3.

In summary, the supporter can be any kind of designs based upon the size of the upper chip, so the upper chip can be disposed entirely on the carrying portion of the supporter or overhangs the supporter with a distance less than 2.5 mm. Accordingly, the upper chip can be designed in different size according to actual need. In such a manner, the upper chip will not be damaged and cracked due to the smaller thickness of the upper chip when the electrically conductive wires bonds the upper chip to the substrate by wire bonding process. Moreover, the supporter can be a heat spreader to be regarded as a thermally conductive device for transmitting the heat generated from the upper chip to external devices through the substrate. Besides, when the lower chip is a high-frequency chip, the supporter can be electrically grounded to the substrate to provide an electrical shielding to avoid noise and cross-link of the electrical signals.

Although the invention has been described in considerable detail with reference to certain preferred embodiments, it will be appreciated and understood that various changes and modifications may be made without departing from the spirit and scope of the invention as defined in the appended claims.

What is claimed is:

1. A multi-chips stacked package, comprising:
a substrate having an upper surface and a lower surface;
a lower chip disposed on the upper surface of the substrate and electrically connected to the substrate;
a supporter having a carrying portion and a supporting portion connecting the carrying portion, wherein the supporting portion is mounted on the upper surface of the substrate and the carrying portion covers the lower chip; and
an upper chip disposed on the carrying portion and electrically connected to the substrate via a plurality of electrically conductive wires.

2. The multi-chips stacked package of claim 1, wherein the upper chip is entirely disposed on the carrying portion.

3. The multi-chips stacked package of claim 1, wherein the thickness of the upper chip is smaller than 5.5 mils.

4. The multi-chips stacked package of claim 1, wherein the upper chip overhangs the carrying portion with a distance less than 2.5 mm.

5. The multi-chips stacked package of claim 1, wherein the supporter is a heat spreader.

6. The multi-chips stacked package of claim 1, wherein the carrying potion and the supporting portion are formed integrally.

7. The multi-chips stacked package of claim 1, wherein the supporter is cap-like.

8. The multi-chips stacked package of claim 1, wherein the carrying portion is a flat plate.

9. The multi-chips stacked package of claim 1, wherein the carrying potion of the supporter further has a protrusion formed at the bottom of the carrying portion.

10. The multi-chips stacked package of claim 1, wherein the supporter is electrically grounded to the substrate.

11. The multi-chips stacked package of claim 1, wherein an adhesive layer is interposed between the carrying of the supporter and the upper chip.

12. The multi-chips stacked package of claim 11, wherein the adhesive layer is made of a thermally conductive adhesive.

13. The multi-chips stacked package of claim 1, further comprising an encapsulation enclosing the upper chip, the lower chip, the supporter and the electrically conductive wires.

14. The multi-chips stacked package of claim 1, wherein the lower chip is a high-frequency chip.

15. The multi-chips stacked package of claim 14, the supporter and the upper surface of the substrate forms a chamber filled with an air.

16. The multi-chips stacked package of claim 1, wherein the lower chip is mounted on the substrate via bumps.

17. The multi-chips stacked package of claim 1, wherein the lower chip is electrically connected to the substrate via electrically conductive wires.

18. The multi-chips stacked package of claim 1, further comprising a plurality of solder balls formed on the lower surface of the substrate.

19. The multi-chips stacked package of claim 1, wherein the supporting portion is in the form of a ring.

20. The multi-chips stacked package of claim 1, wherein the supporting portion is composed of slant columns connecting to the carrying portion.
